(19) United States
(12) Patent Application Publication
(10) Pub. No.: US 2017/0345676 A1
(43) Pub. Date: Nov. 30, 2017

(54) WAFER LEVEL PACKAGING USING A TRANSFERABLE STRUCTURE

(71) Applicant: SKYWORKS SOLUTIONS, INC., Woburn, MA (US)

(72) Inventor: Kezia Cheng, Lowell, MA (US)

(21) Appl. No.: 15/440,233

(22) Filed: Feb. 23, 2017

Related U.S. Application Data
(60) Provisional application No. 62/343,198, filed on May 31, 2016.

(51) Int. Cl. H01L 21/48; H01L 21/52; H01L 23/053; H01L 23/66

(52) U.S. Cl. CPC H01L 21/4817; H01L 23/66; H01L 21/52; H01L 23/053

(57) ABSTRACT

According to various aspects and embodiments, a system and method for packaging an electronic device is disclosed. One example of the method comprises depositing a layer of temporary bonding material onto a surface of a first substrate, depositing a layer of structure material onto a surface of the layer of temporary bonding material, masking at least a portion of the structure material to define an unmasked portion and a masked portion of the structure material, exposing the unmasked portion of the structure material to a source of light, removing the masked portion of the structure material, bonding at least a portion of a surface of a second substrate to the unmasked portion of the structure material, and removing the first substrate from the unmasked portion of the structure material.

### CROSS-REFERENCE TO RELATED APPLICATIONS

This application claims the benefit of priority under 35 U.S.C. §119(e) to co-pending U.S. Provisional Application No. 62/343,198, filed on May 31, 2016, which is incorporated herein by reference in its entirety for all purposes.

### BACKGROUND

Wafer packaged packaging (WLP) for electronic devices often requires processing methods for one or more components that are incompatible with processing used to form other components of these systems. Furthermore, as device sizes and profit margins shrink for these devices, any advantage that can address problems related to incompatible processing, shrinking die sizes, and reduce manufacturing costs would be beneficial.

### SUMMARY

Aspects and embodiments relate generally to the field of semiconductor wafer processing technology. In particular, aspects and embodiments relate to a transferable structure that may be implemented into packaged electronic devices, such as those used in wireless networking applications, and to a method of packaging an electronic device using a transferable structure constructed from a polymer material.

According to certain embodiments, a method of packaging an electronic device includes depositing a layer of temporary bonding material onto a surface of a first substrate, depositing a layer of structure material onto a surface of the layer of temporary bonding material, masking at least a portion of the structure material to define an unmasked portion and a masked portion of the structure material, exposing the unmasked portion of the structure material to a source of light, removing the masked portion of the structure material, bonding at least a portion of a surface of a second substrate to the unmasked portion of the structure material, and removing the first substrate from the unmasked portion of the structure material.

In some embodiments, the layer of structure material is a first layer of structure material and the method further comprises depositing a second layer of structure material onto the unmasked and the masked portions of the first layer of structure material prior to exposing the unmasked portion to a source of light. According to a further embodiment, the method also includes masking at least a portion of the second layer of structure material to define an unmasked portion and a masked portion of the second layer of structure material. According to another embodiment, the method further includes exposing the unmasked portion of the second layer of structure material to a source of light. According to some embodiments, removing the masked portion includes removing the masked portions of the first layer and the second layer of structure material. According to another embodiment, the unmasked portion of the first layer of structure material defines a lid structure and the unmasked portion of the second layer of structure material defines a wall structure. According to certain embodiments, the second substrate includes at least one electronic device disposed on at least a portion of the surface of the second substrate and the lid structure and the wall structure define a cavity that surrounds the at least one electronic device.

In accordance with one embodiment, the method further includes hard baking the unmasked portion of the structure material prior to removing the first substrate.

According to another embodiment, removing the masked portion of the structure material comprises exposing the masked portion of the structure material to a developing material.

According to another embodiment, a method of packaging an electronic device includes depositing a layer of temporary bonding material onto a surface of a first substrate, masking at least a portion of the temporary bonding material to define an unmasked portion and a masked portion of a surface of the temporary bonding material, depositing a layer of structure material onto the unmasked portion of the surface of the temporary bonding material, performing at least a partial cure of the layer of structure material to provide a layer of at least partially cured structure material, bonding a second substrate to at least a portion of the layer of at least partially cured structure material, and removing the first substrate from the layer of at least partially cured structure material.

In some embodiments, the layer of structure material is a first layer of structure material and the method further comprises masking at least a portion of the first layer of the at least partially cured structure material to define an unmasked portion and a masked portion of a surface of the at least partially cured first layer of structure material, and depositing a second layer of structure material onto the unmasked portion of the at least partially cured first layer of structure material prior to bonding to the second substrate.

According to certain embodiments, the method further includes performing at least a partial cure of the second layer of structure material to provide a second layer of at least partially cured structure material.

According to at least one embodiment, the first layer of at least partially cured structure material defines a lid structure and the second layer of at least partially cured structure material defines a wall structure. According to a further embodiment, the second substrate includes at least one electronic device disposed on at least a portion of the surface of the second substrate and the lid structure and the wall structure define a cavity that surrounds the at least one electronic device.

In accordance with various embodiments, performing the at least partial cure comprises heating the layer of structure material at a predetermined temperature for a predetermined length of time. According to one embodiment, performing the at least partial cure comprises exposing the layer of structure material to a source of UV light.

According to at least one embodiment, the at least one electronic device is disposed on a first portion of the surface of the second substrate and the second substrate further includes at least one electrode disposed on a second portion of the surface of the second substrate.

According to another embodiment, the method further includes aligning the wall structure to the at least one electrode.

According to another embodiment, the method further includes bonding a portion of the lid structure to the at least one electrode.

According to another embodiment, the method further includes forming at least one bonding structure.

According to another embodiment, the method further includes dicing the second substrate to form a plurality of packaged electronic devices.

According to another embodiment, the method further includes mounting the at least one electronic device in an electronic device module.

According to some embodiments, the method further includes depositing a layer of metal onto at least a portion of the lid structure prior to bonding.

In another embodiment, a method of forming a transferable structure for packaging an electronic device includes generating a transferable structure from at least one layer of structure material using a first substrate, and transferring the transferable structure to a second substrate, the transferable structure constructed and arranged to define walls and a lid for a cavity that encapsulates at least one electronic device disposed on a surface of the second substrate.

According to another embodiment, the at least one layer of structure material comprises a first layer of structure material that defines the lid and a second layer of structure material that defines the walls.

According to another embodiment, generating the transferable structure comprises inkjet printing the at least one layer of structure material onto a surface of the first substrate.

In another embodiment, a transferable structure for use in packaging an electronic device includes at least one layer of structure material disposed on temporary bonding material that at least partially covers a surface of a preparation substrate, and the at least one layer of structure material is constructed and arranged to form at least a portion of a package that hermetically seals an electronic device.

According to a further embodiment, the at least one layer of structure material is constructed and arranged to form walls and a lid for a cavity that surrounds the electronic device.

According to another embodiment, the layer of structure material is a polymer. In some embodiments, the polymer is a polyimide. In some embodiments, the polymer is photosensitive.

According to another embodiment, the transferable structure is disposed in a packaged module.

In some embodiments, the packaged module is an electronic device module. According to at least one embodiment, the electronic device module is a radio frequency device module. In another embodiment, the electronic device module is included in a duplexer.

In some embodiments, the packaged module is disposed in a wireless communications device.

Still other aspects, embodiments, and advantages of these example aspects and embodiments, are discussed in detail below. Moreover, it is to be understood that both the foregoing information and the following detailed description are merely illustrative examples of various aspects and embodiments, and are intended to provide an overview or framework for understanding the nature and character of the claimed aspects and embodiments. Embodiments disclosed herein may be combined with other embodiments, and references to “an embodiment,” “an example,” “some embodiments,” “some examples,” “an alternate embodiment,” “various embodiments,” “one embodiment,” “at least one embodiment,” “this and other embodiments,” “certain embodiments,” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 is a side view of a cross-section of one example of a preparation substrate with a transferable structure that is attached to a receiving substrate according to one or more aspects of the invention;

FIG. 2 is a flow chart illustrating one example of a method according to aspects of the invention;

FIG. 3 is a flow chart illustrating another example of a method according to aspects of the invention;

FIGS. 4A and 4B illustrate an act in the method of FIGS. 2 and 3;

FIGS. 5A and 5B illustrate an act in the method of FIG. 2 according to a first example;

FIGS. 6A and 6B illustrate an act in the method of FIG. 2 according to the first example;

FIG. 7 illustrates an act in the method of FIG. 2 according to the first example;

FIGS. 8A and 8B illustrate an act in the method of FIG. 2 according to a second example;

FIGS. 9A and 9B illustrate an act in the method of FIG. 2 according to the second example;

FIG. 10 illustrates an act in the method of FIG. 2;

FIGS. 11A and 11B illustrate an example of a receiving substrate in accordance with aspects of the invention;

FIG. 12 illustrates an act in the methods of FIGS. 2 and 3;

FIGS. 13A and 13B illustrate an act in the method of FIGS. 2 and 3;

FIGS. 14A and 14B illustrate an act in the method of FIG. 3;

FIGS. 15A and 15B illustrate an act in the method of FIG. 3 according to a first example;

FIGS. 16A and 16B illustrate an act in the method of FIG. 3 according to the first example;

FIGS. 17A and 17B illustrate alternative embodiments of an act in the method of FIG. 3 according to the first example;

FIG. 18 illustrates an act in the method of FIG. 3 according to a second example;

FIGS. 19A and 19B illustrate an act in the method of FIG. 3 according to the second example;

FIGS. 20A and 20B illustrate an act in the method of FIG. 3 according to the second example;

FIGS. 21A and 21B illustrate an act in the method of FIG. 3;

FIG. 22 illustrates another example of an implementation of the methods of FIGS. 2 and 3;

FIG. 23 illustrates an example of one or more additional acts performed on the example of FIG. 22;

FIG. 24 illustrates an example of one or more additional acts performed on the example of FIG. 23;

FIG. 25A is a photograph taken with a SEM (scanning electron microscope) showing a top view of a structure fabricated in accordance with one or more of the methods of the invention;

FIG. 25B is a figure drawing of the SEM photograph of FIG. 25A;

FIG. 26A is a photograph taken with a SEM showing a top view of six separate structures fabricated in accordance with one or more of the methods of the invention;

FIG. 26B is a figure drawing of the SEM photograph of FIG. 26A;

FIG. 27A is a photograph taken with a SEM showing a perspective view of a partial cross-section of a structure fabricated in accordance with one or more of the methods of the invention;

FIG. 27B is a figure drawing of the SEM photograph of FIG. 27A;

FIG. 27C is a photograph taken with a SEM showing a perspective view of another partial cross-section of a structure fabricated in accordance with one or more of the methods of the invention;

FIG. 27D is a figure drawing of the SEM photograph of FIG. 27C;

FIG. 28 is a block diagram of one example of a device that can be fabricated according to aspects of the present invention;

FIG. 29 is a block diagram one example of a module having one or more features according to aspects of the invention; and

FIG. 30 is a block diagram of one example of a wireless device having one or more features according to aspects of the invention.

### DETAILED DESCRIPTION

Many different applications, such as wafer-level packaging, electronic device fabrication, microfluidic systems, and the like, are implemented using any one of a number of different processing techniques, including those typically used in semiconductor fabrication, such as film coating and/or layering, photosensitive film patterning, etching, bonding, etc. However, these processes often use temperatures and chemicals that are incompatible with polymer materials that may be integrated into the device and/or package. Furthermore, polymer materials may be ideal to use in these kinds of systems due to their low cost and robustness and flexibility in their configuration.

Disclosed herein are examples related to polymer structures for use in wafer-level packaging (WLP) of semiconductor devices, although the systems and methods disclosed herein may also be applied to other applications that are capable of integrating polymer structures, such as electronic and optoelectronic device fabrication, MEMS devices, microfluidic and biomedical devices, and the like. According to some embodiments, the polymer material may be processed to create features and structures that are micrometer or larger in scale. In certain instances, the processes used to produce these polymer structures can include polymer film coating, patterning, wafer-to-wafer bonding, etc. Typical processing methods for creating these structures include fabricating the polymer material directly on a device wafer. However, as discussed above, the polymer structures are often incompatible with other processing steps used in generating the device. One or more of the embodiments disclosed herein include the use of a preparation substrate to create polymer structures that may then be transferred from the preparation substrate and attached to a receiving or device substrate. The systems and methods disclosed herein allow for polymer structures to be created separately and then integrated as a component of the electronic device and packaging. This not only alleviates issues related to incompatible processing methods, but may also reduce costs by consolidating the processing steps used to create the structure constructed from the polymer material(s).

It is to be appreciated that the aspects disclosed herein in accordance with the present invention are not limited in their application to the details of construction and the arrangement of components set forth in the following description or illustrated in the accompanying drawings. These aspects are capable of assuming other embodiments and of being practiced or of being carried out in various ways. Examples of specific implementations are provided herein for illustrative purposes only and are not intended to be limiting. In particular, acts, components, elements, and features discussed in connection with any one or more embodiments are not intended to be excluded from a similar role in any other embodiments.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. In addition, in the event of inconsistent usages of terms between this document and documents incorporated herein by reference, the term usage in the incorporated reference is supplementary to that of this document; for irreconcilable inconsistencies, the term usage in this document controls.

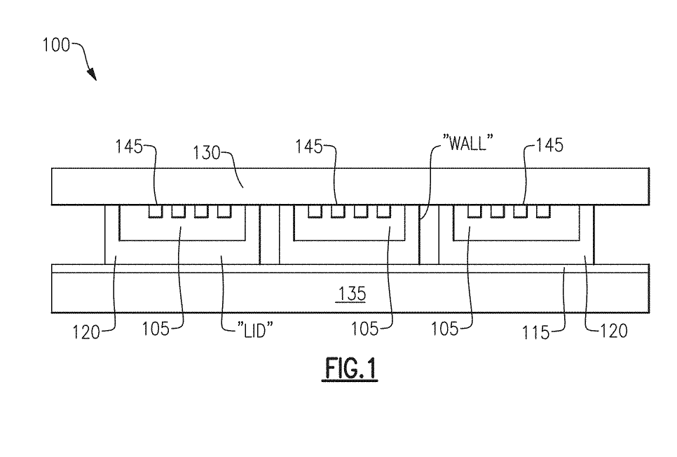

In accordance with one or more embodiments, FIG. 1 illustrates a side view of a cross-section of a preparation substrate 135 (also referred to herein as a carrier substrate) with a structure material 120 that is configured to be transferred and attached to a receiving substrate 130 (also referred to herein as a device substrate), generally indicated at 100. A layer of temporary bonding material 115 is deposited on the surface of the preparation substrate 135. When the temporary bonding material 115 is removed, the preparation substrate 135 may also be removed, leaving the structure material 120 (also referred to herein as a layer of structure material) attached to the receiving substrate 130. As used herein, the term “structure material” may be used to refer to one or more materials which are used to form features that may be implemented into electronic devices or into packaged electronic devices. For instance, as explained further below, the structure material 120 may be configured to form one or more components of an encapsulation structure, such as walls and a lid that form a cavity that surrounds and encapsulates electronic devices 145 that are integrated into the receiving substrate 130. For example, as shown in FIG. 1 the structure material 120 can form the “walls” and “lid” of a plurality of separate cavities 105 that each surround electronic devices 145 disposed on a surface of the receiving substrate 130. According to some embodiments, the wall and lid structures may be constructed together on the preparation substrate 135 and then transferred to the receiving substrate 130. According to some embodiments, the electronic device 145 may include or be part of a larger system, such as a wireless device, as discussed further below. Non-limiting examples of electronic devices 145 include MEMS or acoustic wave devices, such as surface acoustic wave (SAW) filters or bulk acoustic wave (BAW) filters, or other similar acoustic wave components. For example, interdigitated transducer (IDT) electrodes of a SAW filter may be disposed on the receiving substrate 130 within the cavity 105. The methods disclosed herein allow for various features of the packaged device to be processed separately and transferred to the receiving substrate 130.

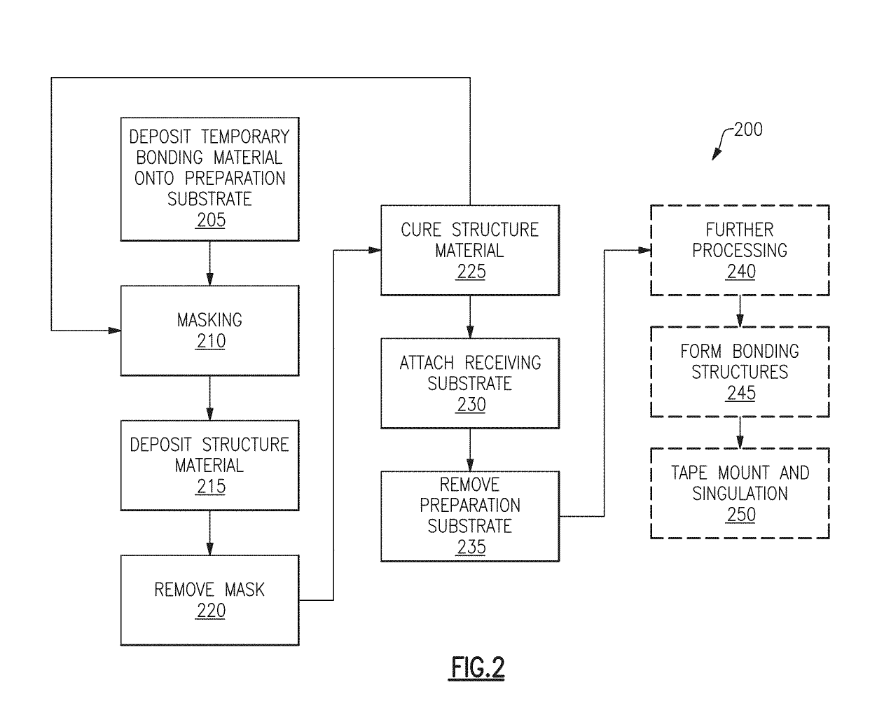

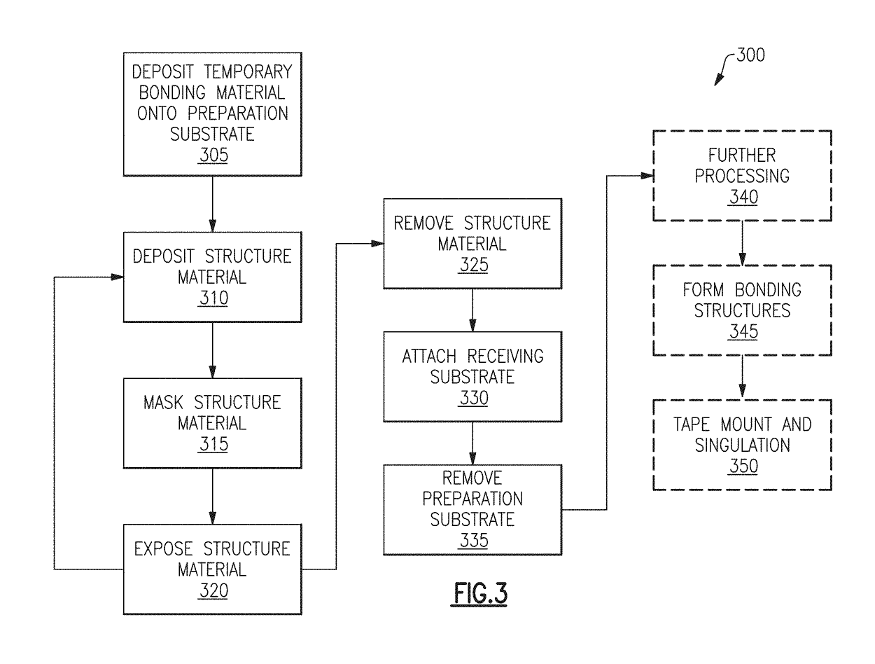

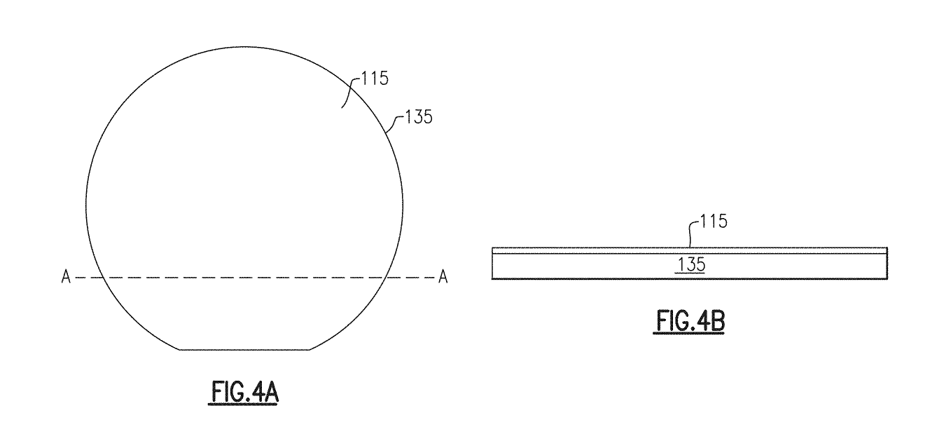

According to various aspects and embodiments, FIG. 2 illustrates a flow diagram of one example of a method 200 of forming a packaged electronic device that includes one or more of the elements discussed above in reference to FIG. 1. Method 200 is described below in reference to FIGS. 4A-6B, 7, 8A-9B, 10, 11A, 11B, 12, 13A and 13B, and comprises a screen printing technique for forming structures that may be integrated into a packaged electronic device. In contrast, method 300, discussed below in reference to FIG. 3, comprises a photolithographic technique for forming the structures.

A first step 205 of method 200 includes depositing a layer of temporary bonding material 115 onto a surface of the preparation substrate 135, as shown in FIGS. 4A and 4B. FIG. 4A is a top view of the preparation substrate 135 and FIG. 4B is a side view of a cross-section taken along dotted line A-A of FIG. 4A. The temporary bonding material 115 allows for relative ease in the removal of the preparation substrate 135 once the structure material 120 has been transferred to the receiving substrate 130. Non-limiting examples of temporary bonding materials include polyvinyl alcohol (PVA), Omnicoat™ (commercially available from MicroChem Corp.), polymethylglutarimide (PMGI), and other low surface energy organic materials. According to at least one embodiment, the temporary bonding material is PVA. According to some embodiments, the temporary bonding material 115 may be a halocarbon, such as tetrafluoromethane (CF₄) or sulfur hexafluoride (SF₆). According to some embodiments, the temporary bonding material 115 may be a material that is capable of being dissolved by selected solvents. The temporary bonding material 115 may be deposited using a spin-coat or spray-coat technique, and depending on the application, the thickness may be in a range of about 2000 Angstroms to several microns. In addition, according to some embodiments, the surface of the preparation substrate 135 is cleaned prior to deposition of the temporary bonding material 115. For instance, the preparation substrate 135 may be cleaned using a Standard Clean 1 (SC1) cleaning solution (i.e., a wet chemical clean), rinsed with water, and then dried, as readily understood by those skilled in the art.

The preparation substrate 135 may be constructed from any one of a number of different materials, including silicon (Si) or glass, and in certain instances may be made of a piezoelectric single crystal material such as, for example, sapphire, lithium tantalite, lithium niobate, quartz crystal, and the like. Other non-limiting examples of suitable preparation substrate materials include glass, zirconium dioxide (ZrO₂), zinc oxide (ZiO), and Al₂O₃. In certain instances, the preparation substrate 135 may be made from the same material as the receiving substrate 130. According to some embodiments, the preparation substrate 135 may be constructed from a material that is transparent to UV light. Non-limiting examples of UV transparent materials include silicon carbide (SiC), sapphire, silicon nitride (SiN), and quartz.

According to one or more embodiments, the preparation substrate 135 is a wafer, as exemplified in FIG. 4A, and may also be referred to herein as a carrier wafer. FIG. 4B is a side view of a cross-section taken along dotted line A-A of FIG. 4A, and illustrates both preparation substrate 135 and the layer of temporary bonding material 115 deposited on the surface of the preparation substrate 135. According to certain aspects, the preparation substrate 135 may be sized and shaped to be approximately the same size and shape as the receiving substrate 130, although in certain instances the preparation substrate 135 may be thicker or otherwise more mechanically robust than the receiving substrate 130. However, the preparation substrate 135 may take on any shape or size that is suitable for a particular application. For instance, the preparation substrate 135 may be a square or circular shape and may be sized to be smaller or larger than the receiving substrate 130.

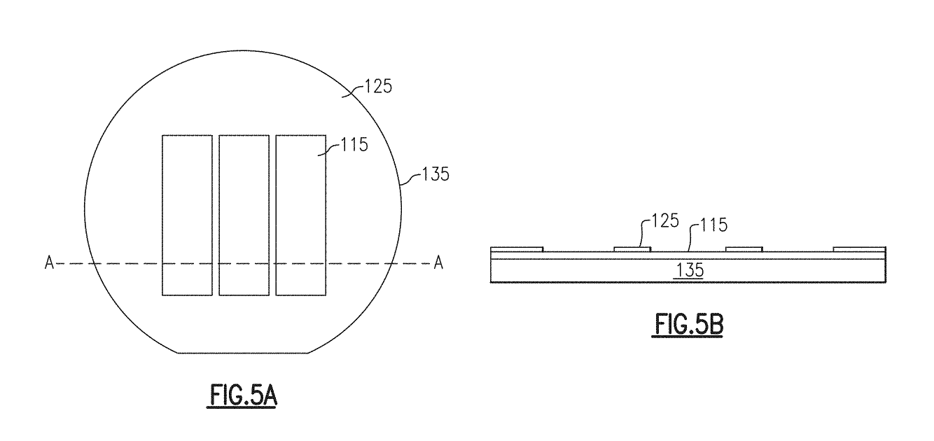

At step 210 of process 200, a masking step is performed. According to some embodiments, at least a portion of the temporary bonding material 115 is masked, as shown in FIGS. 5A and 5B, using a masking material 125 implemented by a stencil, otherwise referred to herein as a shadow mask, or other screen printing technique. For example, FIG. 5A shows a top view of the preparation substrate 135, and FIG. 5B shows a side view of a cross-section taken along line A-A of FIG. 5A. According to some embodiments, step 210 may be accomplished using a stencil (shadow mask), where a shadow mask is positioned over the surface of the temporary bonding material 115. Masking the temporary bonding material may occur when forming a first layer of structure material that is later transferred as a transferred structure formed from one or more layers of structure material. For instance, when forming a lid structure, the surface underlying the shadow mask may be the temporary bonding material 115. Once the lid is formed, other portions of the preparation substrate 135 may be masked, including portions of the temporary bonding material and/or portions of any previously deposited layers of structure material, for instance, for purposes of adding one or more additional layers that form the wall structures.

In accordance with one or more embodiments, the shadow mask may be a planar material with a predetermined pattern of one or more openings that allows exposure to a desired specific region of one or more underlying substrates, such as the preparation substrate 135. In certain instances, the shadow mask may be a thin metal plate with a plurality of openings, and the openings may of any shape or size. Openings in the shadow mask be sized and shaped to correspond to one or more layers that define the desired dimensions for the structure material 120 that is later transferred to the receiving substrate 130, such as the lid and/or wall structures. The masking material 125 may be any material suitable for the purposes of performing a masking function as described in the methods disclosed herein. For example, the shadow mask forming the masking material 125 may be constructed from stainless steel. According to some embodiments, the thickness of the shadow mask may correlate with the resulting thickness of the deposited layer of structure material. However, the thickness of the film may be a function of the mesh size (openings in the stencil) and/or the properties of the structure material, such as the type of epoxy used as the structure material.

According to the specific example shown in FIGS. 5A and 5B, the pattern of the openings in the masking material 125 correspond to “lids” that may be constructed from the structure material 120, and these structures in combination with the “walls” (discussed further below) define a cavity that surrounds one or more electronic devices. For instance, as shown in the top view of the preparation substrate 135 of FIG. 5A, the masking material 125, which may be implemented by a shadow mask, has rectangular-shaped openings that are open to the temporary bonding material 115 positioned below, which is also evidenced in the side view of FIG. 5B which shows a cross-section taken along line A-A of FIG. 5A. The rectangular-shaped openings shown in FIG. 5A correspond to “lid” structures, and the “wall” structures formed in a later step may attach to one or more portions of the lid structures. As discussed in more detail below, the “lid” structure forms the “ceiling” of the cavity 105 that surrounds the electronic device 145, and in certain instances functions to seal the electronic device from the external environment. The example shown in FIG. 5A illustrates three rectangular-shaped lids, although other configurations are also within the scope of this disclosure.

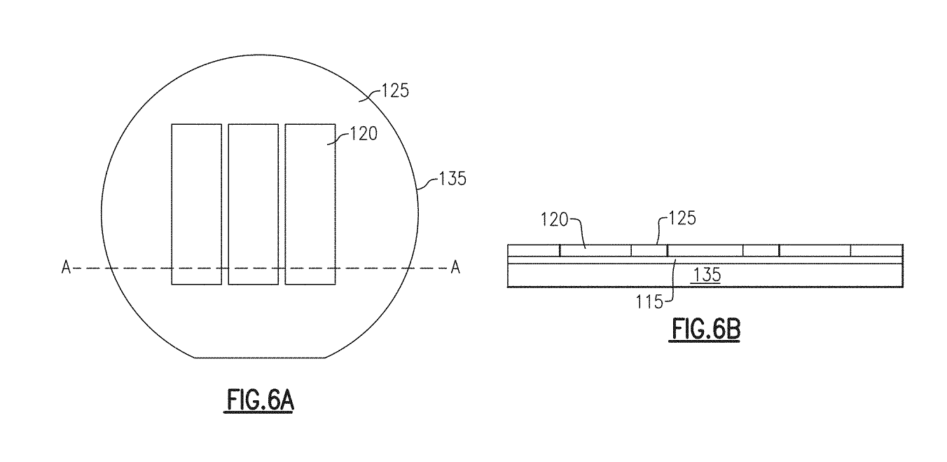

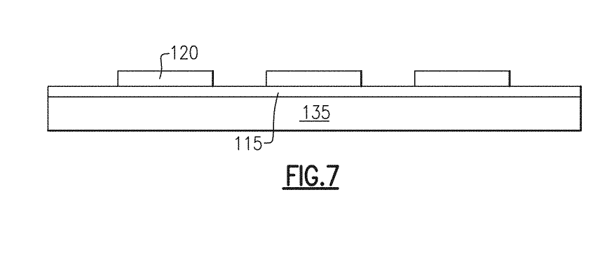

Method 200 further comprises depositing a layer of structure material 120 (step 215) through the masking material 125 onto the temporary bonding material 115, as shown in FIGS. 6A and 6B. Thus, structure material 120 is deposited through the masking material 125 and deposited onto the unmasked portions of the temporary bonding material 115, and the masked portions of the temporary bonding material 115 prevent the structure material 120 from contacting the portions of temporary bonding material 115 that are underneath the masking material 125. FIG. 6A is a top view of the preparation substrate 135 with the structure material 120 deposited through the openings in the masking material 125, and FIG. 6B is a side view of a cross-section taken along line A-A of FIG. 6A. Although FIGS. 6A and 6B show the top of the masking material 125 (corresponding to the “masked” regions of the temporary bonding material 115) being “clear” of structure material 120, the structure material 120 may also be deposited on top of the masking material 125. Once the masking material 125 is removed in step 220, only the open portions of the mask (corresponding to the “exposed” portions of the temporary bonding material 115) will include a layer of structure material 120, as shown in FIG. 7. FIG. 7 is a side view of the preparation substrate 135 with the attached structure material 120 and shows the “lids” that form a portion of the cavity. In certain instances, the shadow mask 125 may be cleaned and used again in a repetitive process.

According to various embodiments, the structure material 120 used in the method 200 of FIG. 2 may comprise one or more polymers. Non-limiting examples of suitable polymers include epoxy materials, such as thixotropic epoxy or other high viscosity polymers. Suitable screen printable polymers may include materials that are commercially available from Epoxy Technology Inc. of Billerica, Mass., including polyimide materials under the trade name EPO-TEK®, such as EPO-TEK® OG159-2, EPO-TEK® OG147-7, and EPO-TEK® OG116. According to at least one embodiment, the structure material 120 may be a photosensitive material, such as a photosensitive epoxy, polyimide, or epoxy-based photoresist material, such as a B-stage polymer. One example of such a material includes SU-8 photoresist (commercially available from MicroChem Corp.).

Once the mask is removed at step 220, the structure material 120 may be at least partially cured at step 225 using any one of a number of different techniques. For instance, curing may be accomplished by heating the structure material 120 at a predetermined temperature for a predetermined amount of time. The temperature and time may depend on the type of material used, as well as the thickness of the material. According to another example, curing may be accomplished by exposing the structure material 120 to a source of light, such as a source of UV light, for a predetermined amount of time. In accordance with some embodiments, the structure material 120 may be at least partially cured according to a cure schedule provided by the material manufacturer. In certain instances, curing functions to fully polymerize and harden the structure material 120, although in some instances a partial cure is performed and then a full cure is done during later processing. For instance, once the receiving substrate 130 is attached, a full cure may be performed. A partial cure may aid in attaching one or more additional layers of structure material. For example, once the lid structures are formed, the structure material 120 may be at least partially cured and then wall structures may be formed on at least a portion of the lid. However, in other instances no cure or a partial cure is performed in between forming the lid and wall structures.

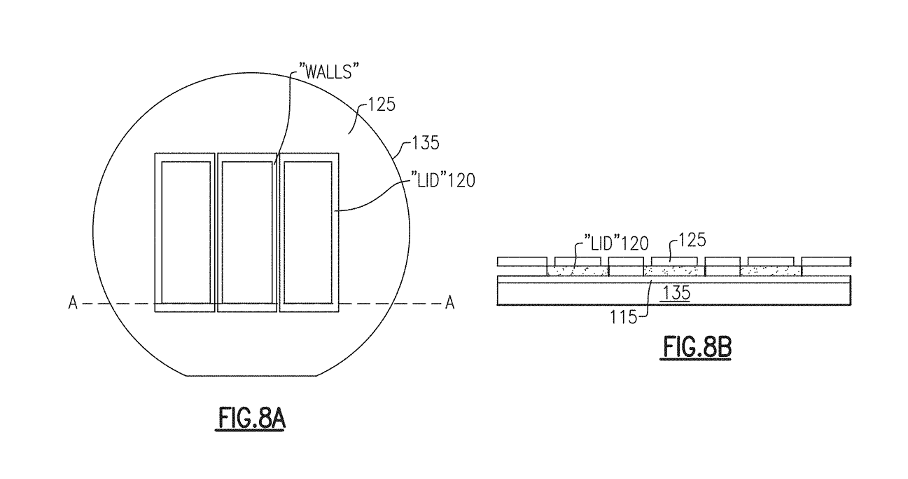

As shown in FIG. 2, additional layers of structure material 120 may be added in a repetitive cycle until a desired structure is formed that is then transferred to the receiving substrate 130. For instance, an additional layer of structure material 120 may be added to the “lids” shown in FIG. 7 to form the “walls.” The process thus returns to the masking step 210 where the preparation substrate 135 is masked, as shown in FIGS. 8A and 8B to form the wall structures. In this instance, portions of the first layer of structure material forming the lid structures are left “open” in the mask 125. The process is similar to that described above in reference to FIGS. 5A-6B, but in this instance the openings in the masking material 125 are configured to create “walls” from structure material 120 that have a size and shape suitable to attach to at least a portion of the lids of structure material 120 that were previously created. Thus, openings of the mask 125 are open to portions of the lid structure, and the openings of the mask 125, as shown in FIGS. 8A and 8B, are configured to correspond to the “wall” structures that surround the electronic device 145. According to some embodiments, the thickness of the walls may be about 0.0010 inches or greater, which in certain instances is much thicker than typical WLP thicknesses. The wall structures in combination with the lid structure form a cavity that functions to encapsulate and seal the electronic device 145.

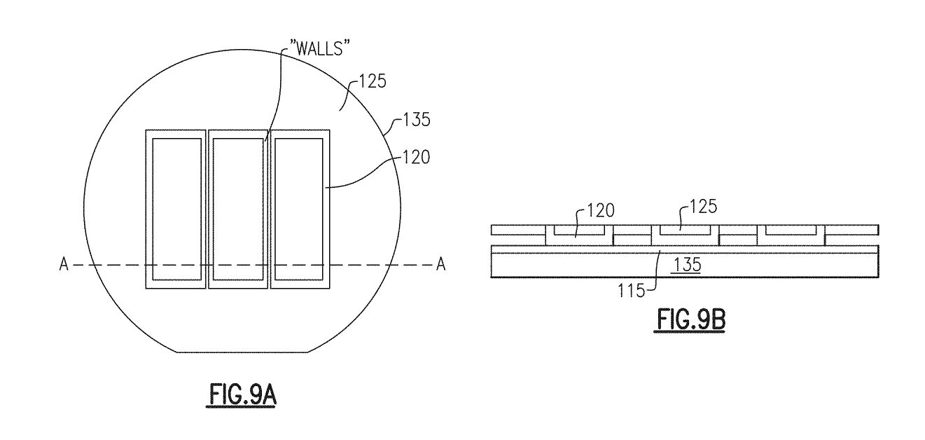

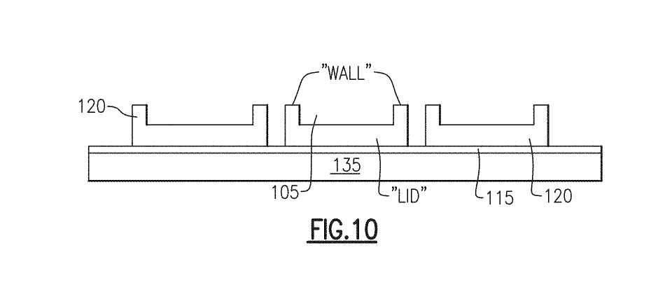

At step 215, structure material 120 is deposited through the openings in the masking material 125, as shown in FIGS. 9A and 9B, which is analogous to the process described above with reference to FIGS. 6A and 6B except for the configuration of the openings in the masking material 125. Once the mask is removed at step 220, the second layer of structure material 120 may be at least partially cured as described above at step 225 by heating or by exposing the structure material to a source of light. According to some embodiments, once the wall structures are formed on the lid, a full cure process may be performed to fully cure the structure material 120 forming the walls and lid. In some embodiments, a full cure is performed after the receiving substrate 130 is attached at step 230. FIG. 10 shows the resulting enclosure formed by the walls and lid (one for each cavity) as disposed on the preparation substrate 135 prior to transferring them to the receiving substrate 130. An alternate embodiment can include one lid structure that covers all three cavities.

According to the example shown in FIGS. 8A-9B and FIG. 10, each enclosure has its own set of walls that are formed on the lid structure. According to other embodiments, each enclosure may share a wall with an adjacent enclosure. Many different configurations of the “walls” and “lid” are also within the scope of this disclosure. For instance, the enclosure may be circular or square-shaped and multiple enclosures may be formed on the preparation substrate, or a single enclosure may be formed on the preparation substrate. In addition, the shadow mask may be positioned within a frame and may be any shape that allows for the openings in the masking material 125 to form the desired features. For instance, the masking material 125 shown in FIG. 5A may be implemented using a shadow mask that is positioned within a frame that extends beyond the outer perimeter of the preparation substrate 135, and therefore the masking material 125 may also extend beyond the outline of the preparation substrate 135.

As will be appreciated, the specific structures discussed herein are examples and other types of structures besides enclosure structures are also within the scope of this disclosure. In addition, the walls and lids discussed herein may be configured differently and assume different shapes and sizes. For instance, round walls and/or lids may be created, lids that cover multiple cavities, only portions of the walls and/or lids may be created, as well as infinite other variations that are also within the scope of this disclosure. In addition, according to some embodiments, the walls and lids may be formed separately and transferred separately.

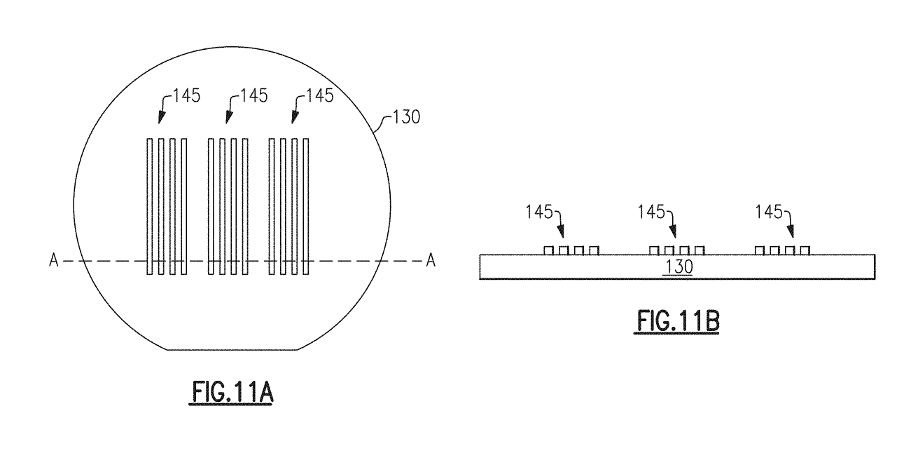

Referring again to FIG. 2, once an at least partial curing step 225 of the structure material 120 is complete, the receiving substrate 130 may be attached to at least a portion of the structure material 120 at step 230. For instance, the walls and lid formed by the structure material 120 may be aligned to features disposed on the receiving substrate 130, such as the electronic devices 145, and then bonded to the receiving substrate 130. According to some embodiments, the structure material 120 may be partially cured at step 225 prior to bonding. A full curing process may also be performed after the structure material 120 is transferred to the receiving substrate 130. FIGS. 11A and 11B show an example of a receiving substrate 130 that includes electronic devices 145 disposed on its surface and is used for purposes of illustration in the examples discussed herein. For instance, according to this example, FIG. 11A is a top view of a receiving substrate 130 that includes three electronic devices 145, and FIG. 11B is a side view of a cross-section taken along line A-A of FIG. 11A. According to some embodiments, the receiving substrate 130 may be a piezoelectric substrate, such as lithium tantalite or sapphire. According to some embodiments, the electronic device(s) 145 may be interdigital transducer (IDT) electrodes of a SAW filter, although other forms of acoustic wave devices or MEMS devices are also within the scope of this disclosure.

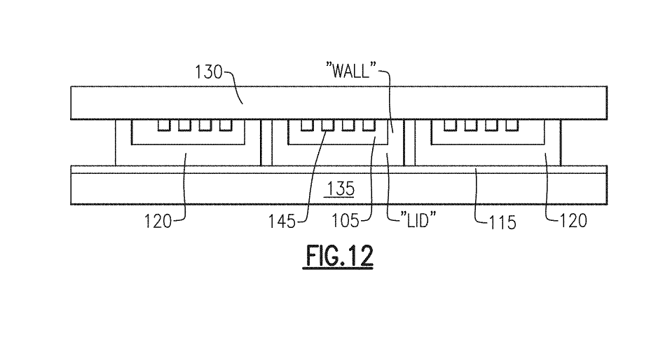

Referring to FIG. 12, the receiving substrate 130 may be attached to the preparation substrate 135 by aligning the lid and walls formed on the preparation substrate to the electronic devices 145 disposed on the receiving substrate 130 and then bonding at least a portion of the walls to the receiving substrate 130. The lids and walls of structure material 120 thereby form a cavity 105 that surrounds the electronic device 145 disposed on the receiving substrate 130. The example of FIG. 12 shows three separate cavities 105 for the three electronic devices 145, which are all identical except for their placement on the receiving substrate 130. These packages may be separated during later processing to form three separate yet identical packages. In some embodiments, the receiving substrate 130 is bonded to the layer of structure material 120 at an elevated temperature under pressure for a predetermined length of time. The temperature and time used during bonding may depend on the type of materials used and the type of electronic device 145 being packaged.

In accordance with some embodiments, the receiving substrate 130 is bonded to the layer of structure material 120 at step 230 at an elevated temperature under pressure for a predetermined length of time. For instance, depending on the structure material used, bonding may be performed at a temperature from about 150° C. to about 300° C. and a pressure of from about 0.5 MPa to about 2 MPa for a time of from about 5 minutes to about 45 minutes. In certain instances the bonding may be performed under vacuum conditions such that the created cavity 105 is under vacuum pressure. In some instances, additional pressure does not need to be applied during the bonding process. According to at least one embodiment, the structure material 120 may be fully cured after the bonding step 230 is performed.

Although FIG. 12 indicates that portions of the layer of structure material 120 are bonded directly to the receiving substrate 130, according to some embodiments, one or more portions of the transferred structure may be bonded to features or structures already disposed on the receiving substrate 130, such as bonding or sealing structures, previously transferred structures, or other features that contribute to the functionality of the package and/or electronic device disposed on the receiving substrate 130. One or more of these features may require processing that is not conducive to the layer of structure material 120 (or vice versa), and therefore it may be advantageous to create and attach the structure material 120 on a separate substrate.

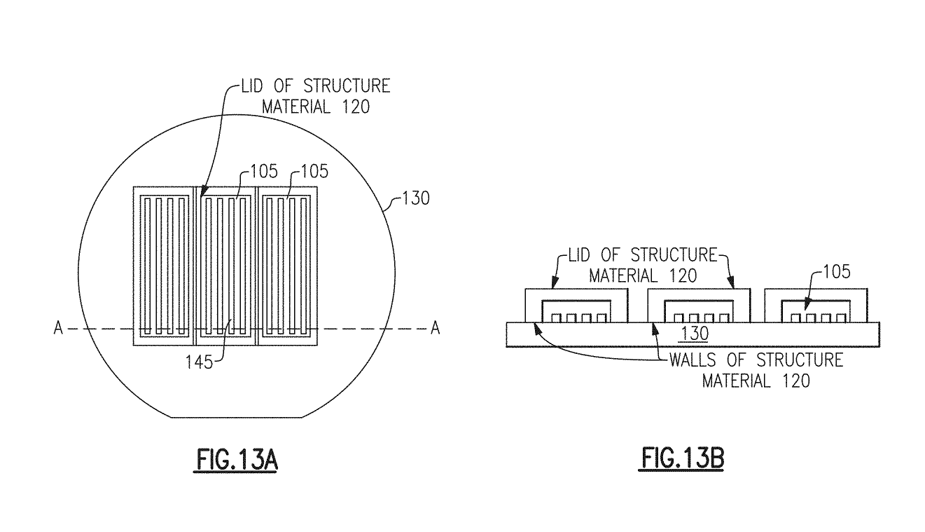

At step 235, the preparation substrate 135 may be removed, thereby leaving the layer of structure material 120 attached to the receiving substrate 130, as illustrated in FIGS. 13A and 13B. For instance, FIG. 13A shows a top view of the lids and walls as attached over the cavities 105 that surround the electronic devices 145, with the lids being shown as partially transparent so as to view the underlying electronic devices 145 disposed within the cavities 105. FIG. 13B is a side view of a cross-section taken along line A-A of FIG. 13A.

The temporary bonding material 115 may be removed using any one of a number of different removal techniques, such as by exposing or otherwise contacting the temporary bonding material 115 with a release agent, such as an inorganic or organic solvent, and/or through a thermal process such as by exposing the temporary bonding material 115 to heat. According to some embodiments, a developer material, including developer products sold by MicroChem Corp. (“MCC”), such as MCC 101 may be used as a release agent. According to some embodiments, the release agent may be an inorganic solvent, such as water. For example, PVA (when used as a temporary bonding material) may be dissolved in water. The release agent may also be one that is recommended by the manufacturer of the temporary bonding material 115. For instance, product information published by the manufacturer of the temporary bonding material 115 may include a list of one or more suitable release agents that may be used for dissolving or otherwise removing the temporary bonding material. According to some embodiments, a “dry” transfer is performed, meaning that the preparation substrate 135 is removed without the use of any liquids such as liquid bonding materials and/or solvents.

Although the receiving substrate 130 illustrated in FIGS. 11A and 11B utilizes an example that includes three “packages,” it is to be understood that the method may be applied to forming multiple packages on a common substrate or wafer. For example, step 250 of FIG. 2 and step 350 of FIG. 3 includes singulation, where the receiving substrate may be diced to individually separate the packaged electronic devices from one another.

In accordance with some embodiments, FIG. 3 illustrates a flow diagram of another example of a method 300 of forming a packaged electronic device, and also includes one or more of the elements discussed above in reference to FIG. 1. As mentioned above, method 300 includes a photolithographic technique for forming structures, such as a lid and wall encapsulation structure, that may be integrated into a packaged electronic device. Method 300 is described below in reference to FIGS. 4A-B, 12, 13A-17B, 18, and 19A-21B, and includes some steps that are similar to method 200 of FIG. 2 discussed above. In addition, the materials used for the preparation substrate 135 and its preparation, and some of the materials used for the structure material may be the same as described above.

A first step 305 of method 300 includes depositing a layer of temporary bonding material 115 onto a surface of the preparation substrate 135, as shown in FIGS. 4A and 4B. This is similar to the process as described above in reference to step 205 of method 200.

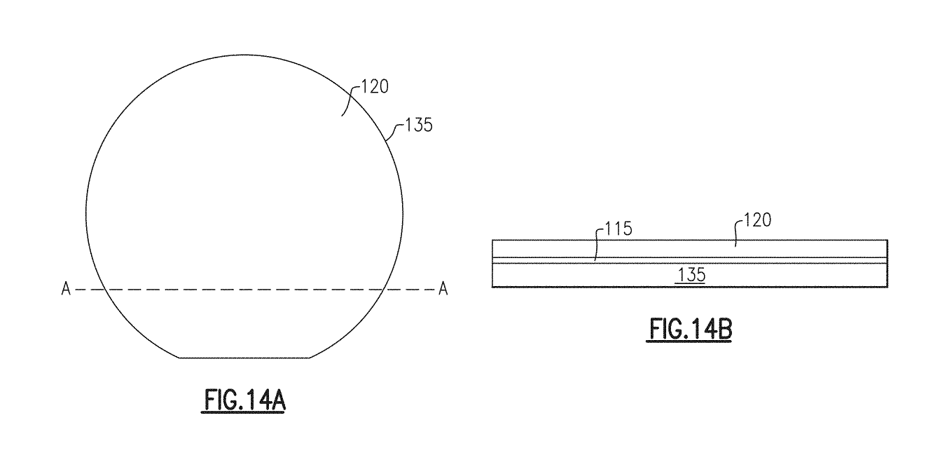

The photolithographic method described below may also be used to form the “lid” and “walls” structures described above. At step 310, a layer of structure material 120 is deposited onto the preparation substrate 135. FIG. 14A shows a top view of the layer of structure material deposited onto the preparation substrate 135 and FIG. 14B is a side view of a cross-section taken along line A-A of FIG. 14A, and shows the layer of structure material 120 disposed directly onto the upper surface of the temporary bonding material 115. According to certain aspects, the layer of structure material 120 may be deposited using spin-coat or spray-on techniques.

In accordance with various embodiments, the layer of structure material 120 may include one or more polymer materials. In some embodiments, the polymer material may be a polyimide material, such as polyimide resin. According to one embodiment, the polymer may be photosensitive such that when the material is exposed to light, such as ultraviolet (UV) light, the photosensitive material reacts. In certain instances, the UV light causes crosslinking between polymer chains that results in forming a stable polymeric network, thereby hardening the material. Non-limiting examples of photosensitive materials include photosensitive epoxies, polyimide, and epoxy-based photoresist materials, such as B-stage polymers. Some examples of these materials include SU-8 photoresist (commercially available from MicroChem Corp.), benzocyclobutene (BCB), and mr-I 9000 (commercially available form Micro Resist Technology Gmbh). In some embodiments, the thickness of the structure material is from about 3 microns to about 5 microns, although other thicknesses are within the scope of this disclosure. As will be understood by those of skill in the art, the thickness of the structure material may depend on the desired application, i.e., how thick or thin the desired features are to be.

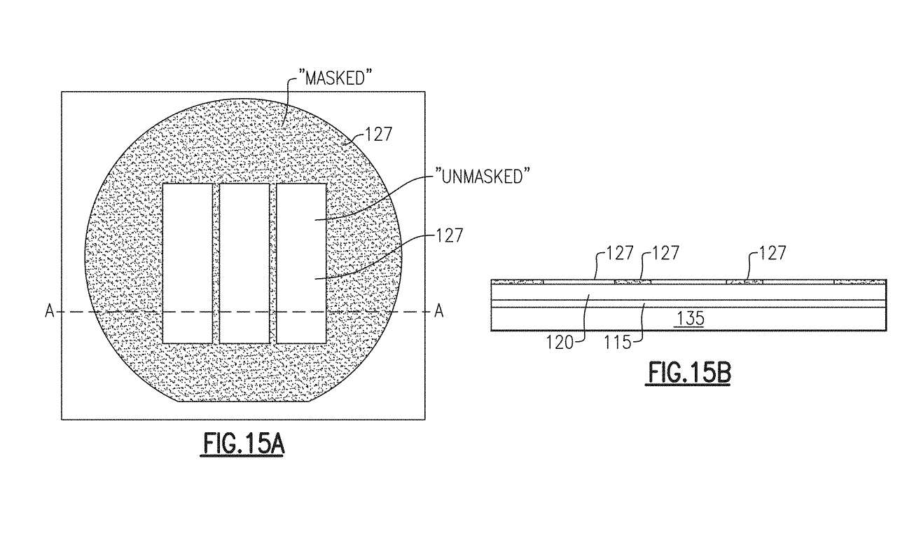

The structure material 120 is masked at step 315 to create unmasked and masked portions of the structure material 120. According to some embodiments, a photolithographic mask 127 (also referred to herein as a photomask) is used to perform this step, as shown in FIGS. 15A and 15B. For example, FIG. 15A illustrates a top view of a photolithographic mask 127 with a pattern that corresponds to the unmasked and masked portions of the underlying structure material 120, and the cross-section taken along line A-A is shown in FIG. 15B. The photolithographic mask 127 is physically different than the shadow mask discussed above in reference to masking material 125 in that it is constructed from a solid material, such as glass, quartz, or fused silica that is coated with an opaque film (e.g., chrome), into which the desired pattern is etched, and therefore does not include openings where material can be deposited through the mask. Rather, the “masked” portions of the photolithographic mask 127 include light-blocking material (such as chrome) and the “unmasked” portions allow light to pass through to the underlying layer of material.

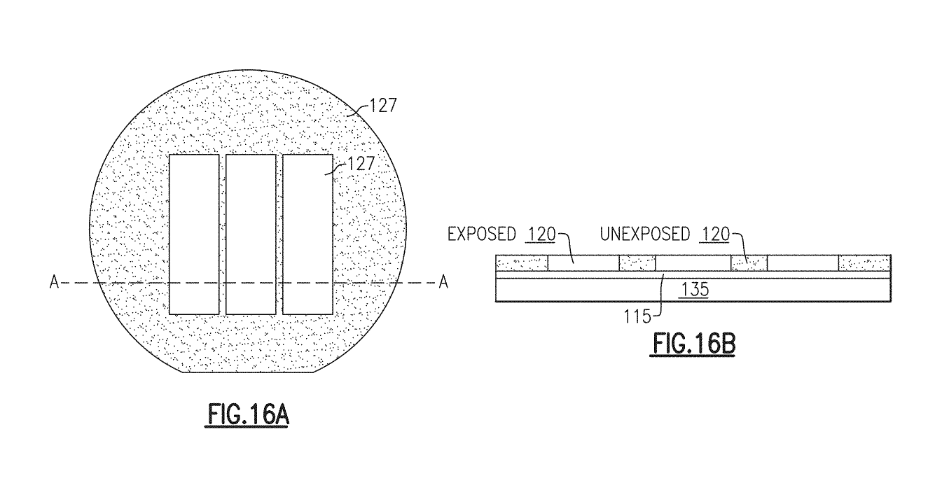

In step 320 and as illustrated in FIGS. 16A and 16B (with the photomask 127 removed), the layer of structure material 120 is exposed to light, such as UV light, through the photomask 127, thereby causing the exposed (i.e., “unmasked”) portions of the structure material 120 to at least partially polymerize. The unexposed (i.e., “masked”) portions of the structure material 120 do not polymerize since the photomask 127 functions to reflect (or absorb, depending on the material) the light. As shown in FIG. 16B, the exposed portions of the structure material correspond to “lid” structures that will be used to form a portion of the cavity that encapsulates the electronic devices 145 disposed on the receiving substrate 130.

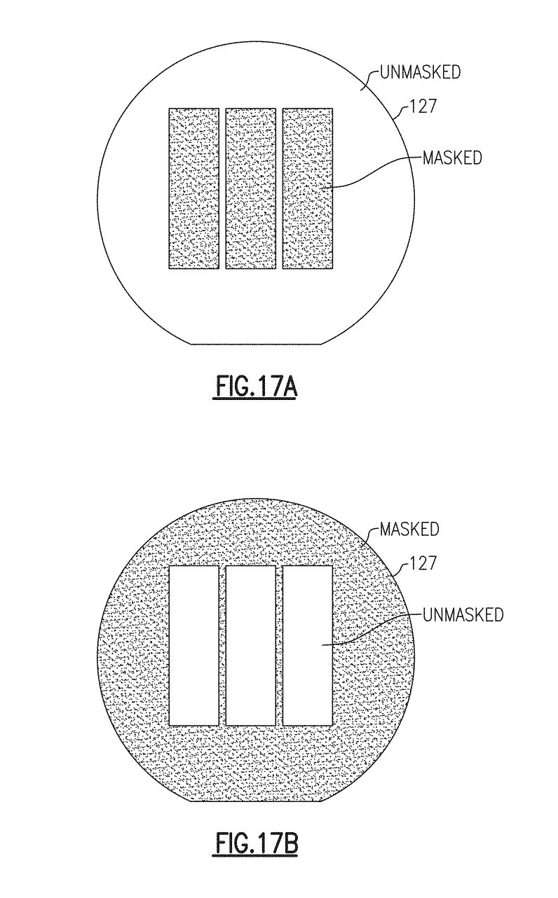

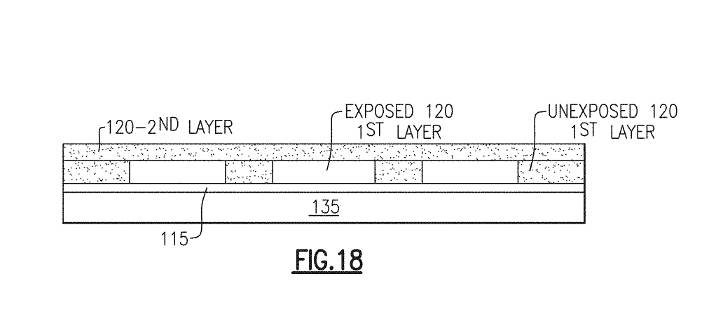

The photolithographic processes discussed herein with reference to method 300 for forming structures references a type of photosensitive material that polymerizes or otherwise reacts with light to form a hardened layer. According to this type of embodiment, the photomask 127 that is used corresponds to the example shown in FIG. 17B, which shows a photomask 127 similar to that shown in FIG. 15A that is configured to form the lid structures. As will be appreciated by those of skill in the art, other types of photosensitive material may be used as the structure material, such as those that actually photo-solubilize when exposed to light. Thus, exposed portions of this type of material are removed, and the unexposed portions form the structures that are then transferred to the receiving substrate. According to this type of embodiment, the photomask 127 that is used corresponds to the example shown in FIG. 17A, which reverses the unmasked and masked portions of the photomask of FIG. 17B. Thus, the portions exposed to light are developed or otherwise removed at step 325, and additional steps may be performed to render this type of structure material suitable for transfer. For instance, an additional curing step may need to be performed, where the structure material may be exposed to heat and/or light of a different wavelength(s).

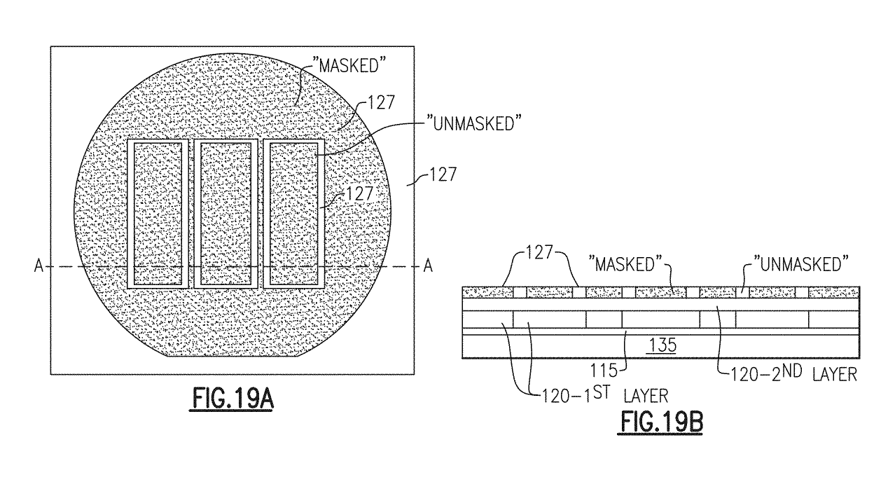

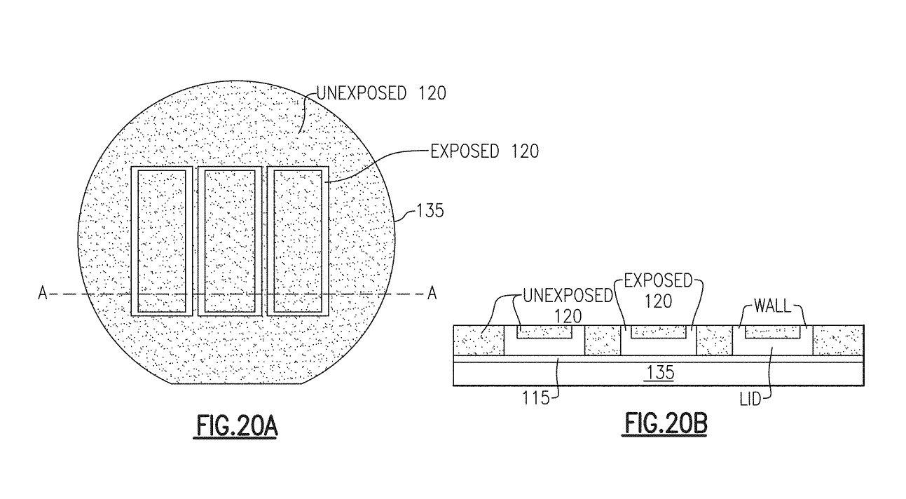

As indicated in FIG. 3, the deposition 310, masking 315, and exposure 320 steps may be repeated to add additional layers of structure material 120. For instance, as shown in FIG. 18, an additional, second layer of structure material 120 may be spin-coated or otherwise deposited onto the existing exposed/unexposed portions of the structure material formed as shown in FIG. 16B. This second layer of structure material 120 may be configured to form the wall structures of the enclosure discussed above. A photomask 127 with unmasked portions corresponding to wall structures is positioned over the second layer of structure material 120, as shown in FIGS. 19A and 19B according to step 315. At step 320, the second layer of structure material 120 is exposed to light, through the photomask 127, which results in unexposed and exposed regions of the second layer of structure material, as shown in FIGS. 20A and 20B (with the photomask 127 removed). As shown in FIG. 20B, the exposed portions of the second layer of structure material 120 correspond to the wall structures, and are formed on portions of the previously formed lid structures, i.e., the edges of the lid structures.

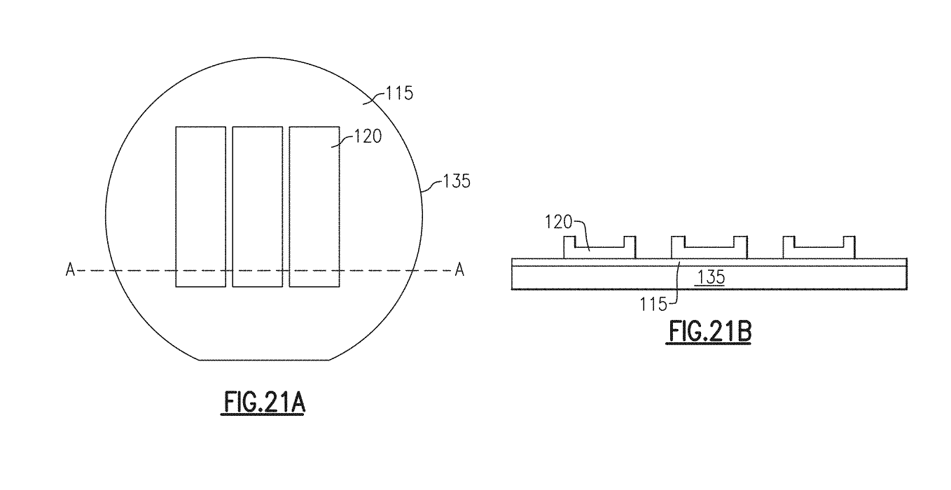

The unexposed portions of structure material remain unreacted and may be developed or otherwise removed in step 325 using any one of a number of different removal techniques, such as by exposing the structure material 120 to a solvent, which results in the wall and lid structures shown in FIG. 21B, which is similar to the structures shown in FIG. 10. FIG. 21A is a top view of the wall and lid structures formed after the unexposed portions have been removed, and FIG. 21B is the cross-section of the preparation substrate 135 taken along line A-A of FIG. 21A. The at least partially polymerized (exposed) portions of the structure material 120 corresponding to the unmasked regions of the photomask 127 are resistant to the solvent, and therefore only the masked portions are removed. In this instance, and as indicated in FIGS. 20B and 21B, the unexposed portions of both the first layer (which resulted in the lids) and the second layer (which resulted in the walls) of structure material 120 are developed or otherwise removed in step 325. According to one embodiment, portions of the unreacted structure material may be developed or otherwise removed in step 325 using one or more organic solvents, such as an SU-8 developer material (commercially available from MicroChem Corp.) or propylene glycol methyl ether acetate (PGMEA), in instances where SU-8 is used as the structure material 120.

In some embodiments, exposing the layer of structure material 120 may be done in such a way as to not fully polymerize the structure material, e.g., by limiting the amount of time the material is subjected to light and/or limiting the intensity or wavelength(s) of light. For instance, a partial polymerization process may be performed such that the at least partially reacted structure material remains in a state that allows for additional layers of structure material to be added and/or for the at least partially reacted material to be bonded to the receiving substrate 130 (discussed in further detail below) in step 330. Once a desired structure is created, such as a wall and lid encapsulation structure, the entire structure may be subjected to an additional exposure step or otherwise treated to “fully” react the material after transferring the structure to the receiving substrate 130.

Referring back to FIG. 3, at step 330 the receiving substrate 130 is attached to at least a portion of the layer of structure material 120, as illustrated in FIG. 12. For example, the walls and lid formed by the structure material 120 may be aligned to features disposed on the receiving substrate 130, such as the electronic devices 145, and then bonded to the receiving substrate.

In certain instances, the structure material 120 may be treated before or after exposure to light so as to render it capable of bonding, such as by performing a soft-cure step before bonding. According to some embodiments, the layer of structure material 120 may be soft baked prior to exposure to light. For example, certain structure materials, such as photoresist, may be soft baked prior to exposure, and then after exposure, undergo a post exposure bake (PEB). Once developed, the photoresist may undergo a hard bake, although according to some embodiments a hard bake is not performed after develop. In some embodiments, a shortened or half cure is performed prior to bonding. For instance, SU-8 may be soft baked prior to exposure at 95° C. for a time period that depends on the thickness and the type of SU-8 material. After being exposed, a shortened or half cure of the photoresist may be performed prior to bonding. In some embodiments, a PEB process may be performed prior to develop and prior to bonding. For instance, SU-8 material may undergo a PEB process at temperatures of about 65° C. and/or about 95° C. for a time period that depends on the thickness and type of SU-8 material (e.g., from 1-5 minutes). According to some embodiments, the temperature and/or time may be reduced for the soft bake and/or PEB (as compared to the times and temperatures recommended by the material manufacturer). Soft bake and PEB may also be used in instances where multiple layers of polymer are formed. For example, a first layer of polymer structure material may be partially cured, and then a second layer of polymer structure material may be deposited on top of the first layer. Once transferred, both layers may be hardened by performing a PEB and optionally a hard bake process. According to embodiments where a hard bake is performed, the hard bake may be performed at a temperature in a range of about 150° C. to about 250° C. for up to 30 minutes (depending on thickness and type of photoresist).

According to at least one embodiment, the receiving substrate 130 is bonded to the layer of structure material 120 at step 330 at an elevated temperature under pressure for a predetermined length of time. For instance, when SU-8 is used as the structure material 120, the bonding conditions may be at a temperature from about 150° C. to about 300° C. and a pressure of from about 0.5 MPa to about 2 MPa for a time of from about 5 minutes to about 45 minutes. In one embodiment, the bonding conditions are performed such that they are appropriate for B-stage SU-8. In addition, the bonding process may be performed under vacuum conditions. In certain instances, this may create a cavity 105 that is also under vacuum pressure. According to some embodiments, additional pressure does not need to be applied during the bonding process. According to some embodiments, after the bonding step is performed, the polymer structure material may be hard cured or otherwise fully cured.

At step 335, the preparation substrate 135 may be removed, thereby leaving the lid and wall structures formed from the structure material 120 attached to the receiving substrate 130, previously described, and as illustrated in FIGS. 13A and 13B.

As indicated by the arrows in FIGS. 2 and 3, multiple layers of structure material may be added to the preparation substrate 135. This allows for individual layers having different sizes and shapes to be combined on a preparation substrate. The transferred structure may therefore include layers with varying shapes and sizes. For example, a first layer of structure material may have a first size and shape, and a second layer may have a second size and shape. In the examples shown herein and in accordance with at least one embodiment, the first layer of structure material may form the lid of a cavity and/or packaging structure, and the second layer may form the walls of for the cavity. When the layers are combined, the entire structure may be transferred to the receiving substrate 130. In addition, a first layer of structure material may have a first composition of one or more polymers, and a second layer of structure material may have a composition of one or more polymers that is different than the first layer. According to other embodiments, multiple layers of different polymer compositions may be deposited so that the single transferred structure includes these different compositions. According to other embodiments, the wall and lid structures described herein may be formed separately on the preparation substrate 135 and transferred to the receiving substrate 130 in individual transfer steps.

Although not explicitly shown in methods 200 and 300 of FIGS. 2 and 3, according to some embodiments, the preparation substrate 135 may be recycled and reused after it has been removed from the receiving substrate 130. Thus, the preparation substrate 135 may be used over and over again in multiple processes.

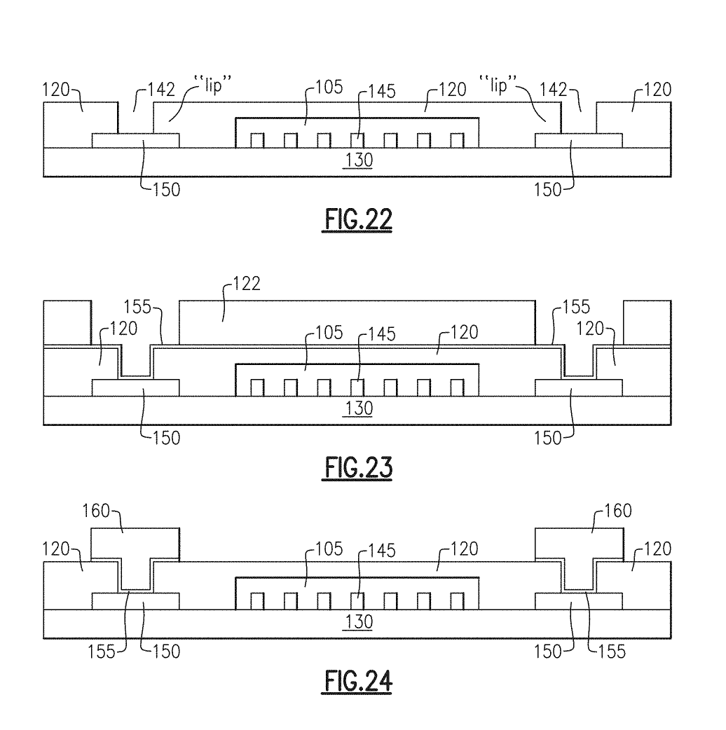

Steps 240, 245, and 250 of FIG. 2 and steps 340, 345, and 350 of FIG. 3 may optionally be performed using the receiving substrate 130 with the attached structure material 120. For example, in step 240 or 340, other layers of material may be added and/or removed that provide functionality to the electronic devices or packaging that houses the devices. In step 245 or 345, bonding structures may be added to the device substrate. As discussed in more detail below, according to some embodiments via openings may be formed through the structure material 120 that surrounds the cavity 105. The via openings may extend to the underlying receiving substrate 130 (or bonding structures formed thereon, such as the electrode 150 as shown in FIGS. 22-24). These vias may subsequently be filled with conductive material, such as metal. In certain instances, these bonding structures, such as the conductive vias, form the electrical contact between elements of the package, such as the electronic devices disposed within the cavity, and the outside of the package. According to some embodiments, sealing structures may be added to regions of the receiving substrate 130 that are outside the cavity 105. These may aid in sealing the packaged device from external environments outside the package. A non-limiting example of further processing and bonding is discussed below in reference to FIGS. 22-24. Each of steps 250 and 350 includes tape mounting the packaged devices to an adhesive-coated tape, and then performing singulation using a die cutting process.

According to at least one embodiment, a layer of metal may be deposited onto at least a portion of the lid and/or wall structure prior to transferring to the receiving substrate 130. For instance, a layer of metal may be deposited onto one or more portions of the layer of structure material 120 corresponding to the “inner” surface of the lid. The resulting cavity may therefore have one side comprising a metal material, which in certain instances may aid in providing a hermetic seal and may also help prevent or reduce outgassing, which can improve device performance. The metal material may be deposited using any one of a number of different techniques. For instance, the layer of metal may be sputtered, and then portions of the metal material may be removed using a subtractive etch or lift off process.

Processes 200 and 300 of FIGS. 2 and 3 each depict one particular sequence of acts in a particular embodiment. The order of acts can be altered, or other acts can be added, without departing from the scope of the embodiments described herein. For instance, in process 200, the structure material 120 may be at least partially or fully cured after attaching the receiving substrate 130, and in process 300 a cure or partial cure of the structure material 120 may take place before and/or after exposure and/or after the receiving substrate 130 is attached. In addition, process 300 may include removing unexposed portions of the existing layers of structure material (step 325) prior to depositing additional layer(s) of structure material (step 310).

In accordance with some embodiments, the structure material 120 may be deposited directly onto either the preparation substrate 130 and/or the receiving substrate 135 using an inkjet printing technique. For example, a preparation substrate 135 may be prepared by depositing a layer of temporary bonding material (as described above in reference to steps 205 and 305) and then the structure material 120 may be deposited in an uncured state by an inkjet printer that has been configured to deposit the structure material 120 into a desired pattern, such as the wall or lid or combination of the wall and lid as described above. Once deposited, the structure material may be at least partially cured and then transferred or otherwise bonded to the receiving substrate 130.

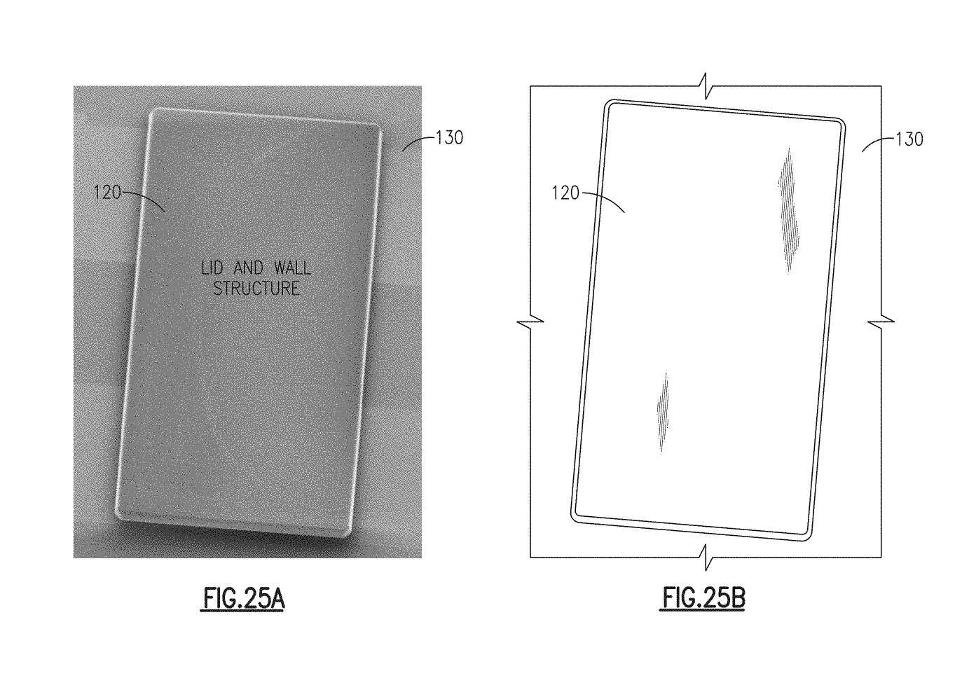

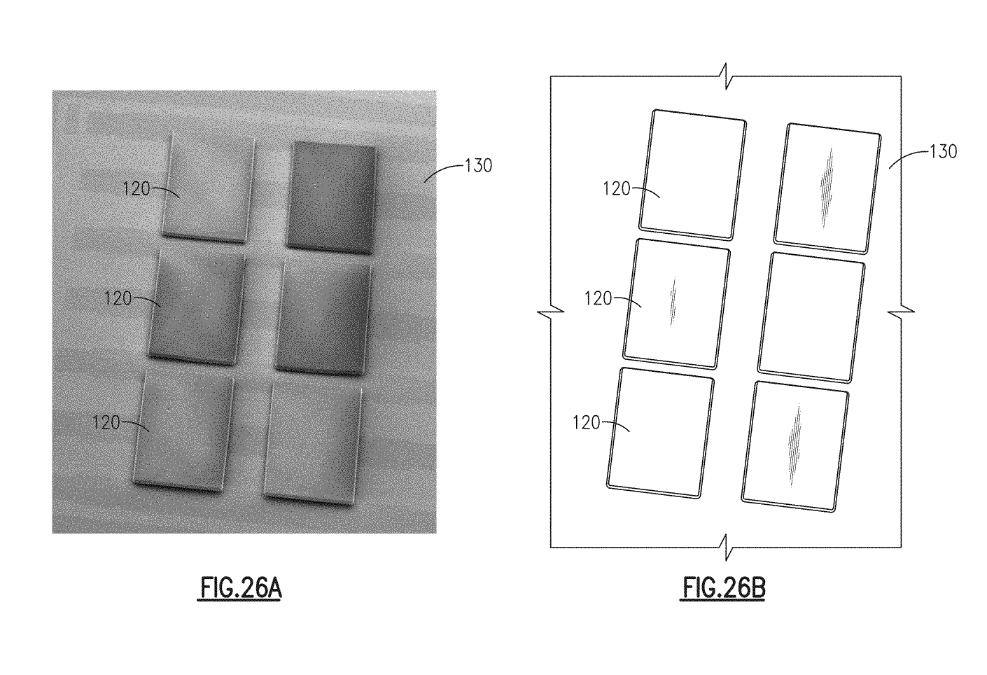

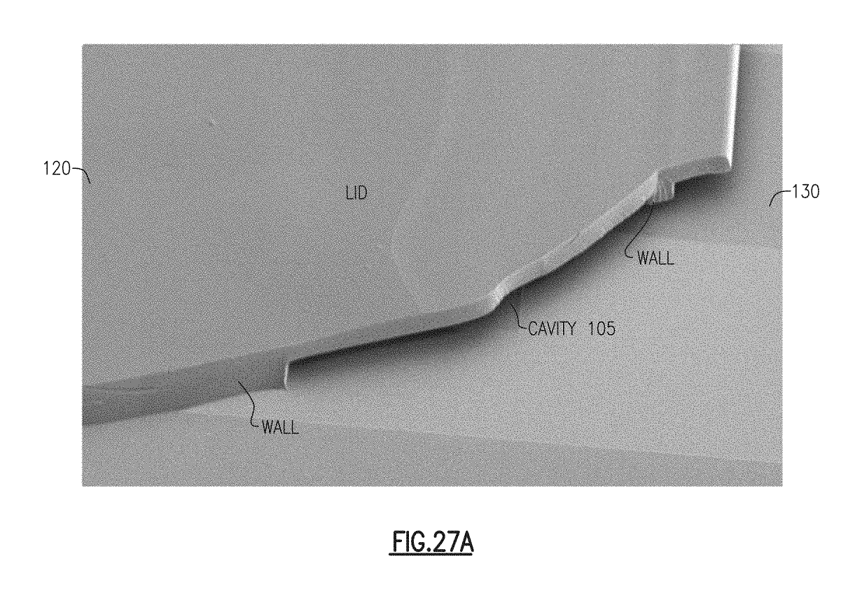

In accordance with some embodiments, FIG. 22 illustrates an example of a receiving substrate 130 that includes one or more electrodes 150 that are disposed or otherwise provided on an upper surface of the receiving substrate 130. As shown in FIG. 24, the electrodes 150 may be attached to or form at least a portion of a bonding structure that surrounds the cavity 105 and forms bond pads that allow for electrical contact between elements of the package (e.g., electronic devices 145) and the outside of the package. According to this and other embodiments, the structure material 120 may be configured to bond to the receiving substrate 130 as well as to at least a portion of the electrode 150. For instance, the structure material 120 may be configured using the deposition and transfer methods discussed herein to form a structure similar to that shown in FIG. 22. In this instance, the structure material 120 includes a “lip” that bonds to at least a portion of the electrode 150. According to some embodiments, the structure material 120 covers the entirety of the electrode 150 and a via opening 142 is formed by performing an etch or other removal-type process to remove a portion of the structure material 120. According to one example, the structure material 120, including the “lip” feature, may be formed according to any of the screen printing, photomasking, or ink-jet printing methods described herein. For instance, a three-step photolithographic process may include first forming a lid in a first layer on the preparation substrate, then using a second layer of structure material to form a first portion of the wall, and then using a third layer of structure material to form the second portion of the wall that is adjacent the lip feature. The entire structure may then be transferred to the receiving substrate 130. A via opening 142 that extends to the electrode 150 may then be formed through the structure material 120 disposed on the electrode 150.

Additional processing to the receiving substrate 130 is shown in FIG. 23. According to one or more embodiments, a metal seed layer 155 may be deposited on at least a portion of the outer surface of the structure material 120 that surrounds the cavity 105. As shown in FIG. 23, the metal seed layer 155 may also be formed on at least a portion of the outer surface of the electrode 150. The metal seed layer 155 may be deposited using PVD methods, such as sputtering or evaporative techniques. According to at least one embodiment, the metal seed layer 155 may comprise copper (Cu) or gold (Au), which are deposited as a seed layer using a sputter technique. According to some embodiments, the metal seed layer may be nickel (Ni). In accordance with various embodiments, the metal seed layer 155 may be any plated metal that doesn't otherwise interfere with the functionality of the electronic device 145 or process for manufacturing and packaging the electronic device 145. According to some embodiments, the seed layer may be used for electroplating and provides a conducting layer onto which the electroplated metal is deposited. Although not shown in the figures, according to some embodiments, a barrier layer of titanium tungsten (TiW), nickel vanadium (NiV), or titanium (Ti) may be used as an adhesion layer for the metal seed layer. In addition, these materials may function to protect diffusion of the metal seed layer 155 into one or more underlying layers. For instance, a layer of TiW may be deposited on the structure material 120 and/or within via opening 142 prior to depositing the metal seed layer 155.

Referring again to FIG. 23, a layer of photoresist material 122 may be deposited onto the metal seed layer 155 using a spin-coat technique for purposes of creating conductive pads 160 within the via openings 142. For example, referring to FIG. 24, a conductive pad 160 formed from conductive material may be formed within via opening 142 of the structure material 120, and as shown in FIG. 24, may also be formed on at least a portion of an outer surface of the structure material 120. The material forming the conductive pad 160 may extend through at least a portion of the depth of the structure material 120, and also contact at least a portion of the outer surface of the metal seed layer 155. According to various aspects, the conductive pad 160 may be a bond pad, as readily understood by those of skill in the art. The conductive pad 160 may be formed using typical lithography techniques such those discussed herein, and shown in FIG. 23. For instance, the photoresist 122 of FIG. 23 may be masked using a photomask similar to the photomask described above but is configured to create the areas that form the final pad structure. The photoresist 122 is then exposed and developed to create the openings for the material forming conductive pad 160. The conductive material forming the conductive pad 160 may then be deposited into the openings created and shown in FIG. 23. Once the material for the conductive pad 160 is deposited, the photoresist 122 may be removed (FIG. 24).

Referring to FIG. 24, portions of the metal seed layer 155 may be removed to form bond pads that allow for electrical contact between elements of the package, (e.g., electrodes) and the outside of the package. The metal seed layer 155 may be removed using an etch method, such as a wet etch processing technique using peroxide, potassium iodide (KI), or acid based solutions, as recognized by those skilled in the art.

FIG. 25A is a SEM image, and FIG. 25B is the corresponding figure drawing, each showing a top view of a wall and lid structure formed from structure material 120 that was created using a photolithographic construction method such as process 300 described above in reference to FIG. 3 and then transferred to a receiving substrate 130. FIG. 26A is a SEM image, and FIG. 26B is the corresponding figure drawing of FIG. 26A, each showing a top view of six separate lid and wall structures similar to the lid and wall structure of FIG. 25 that were also successfully transferred to the receiving substrate 130. The six lid and wall structures were all created and transferred at the same time.

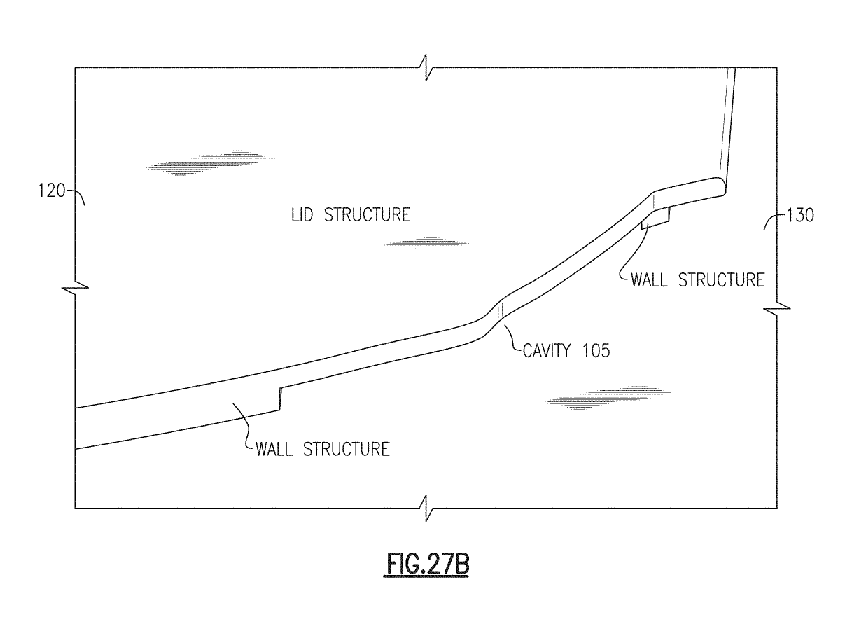

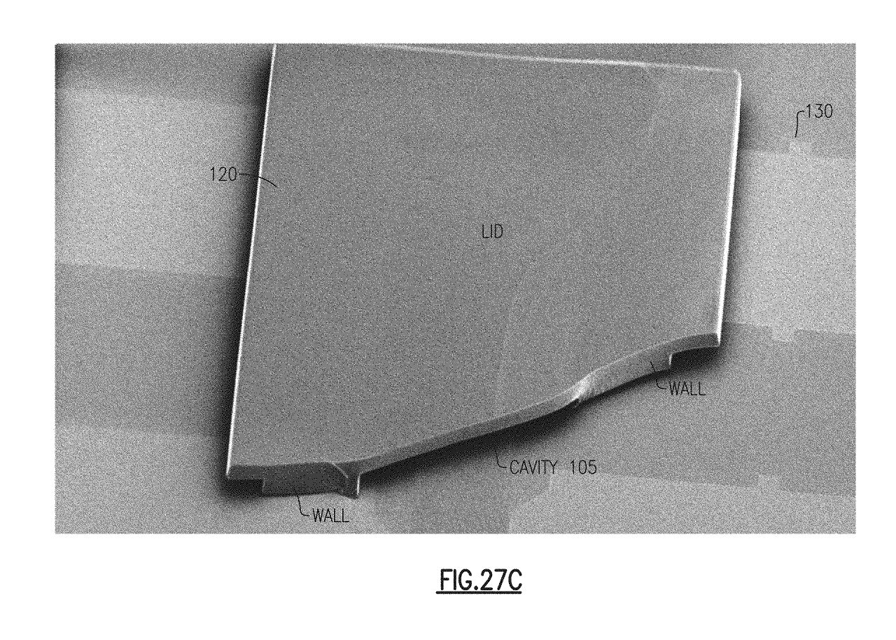

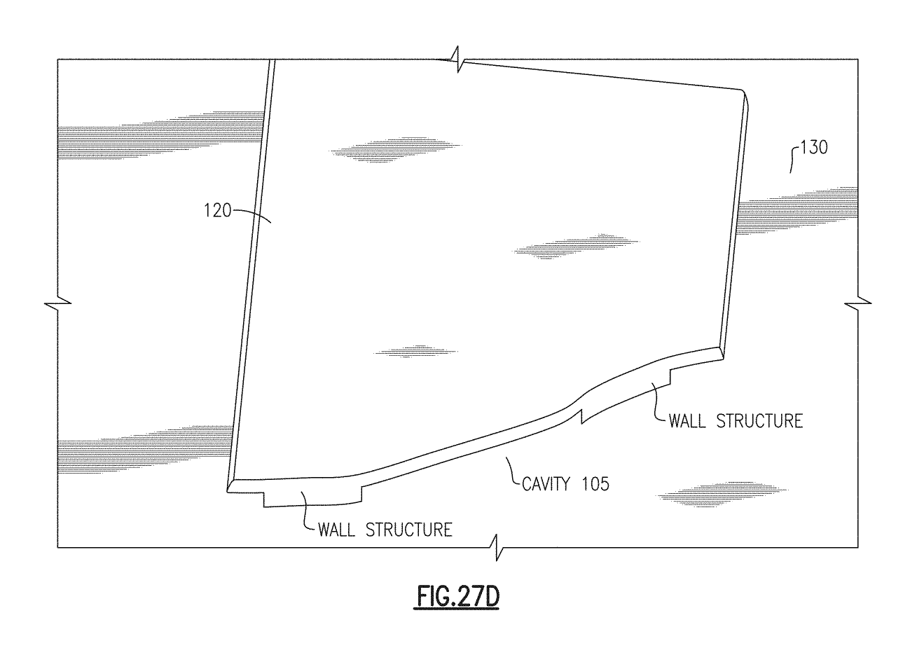

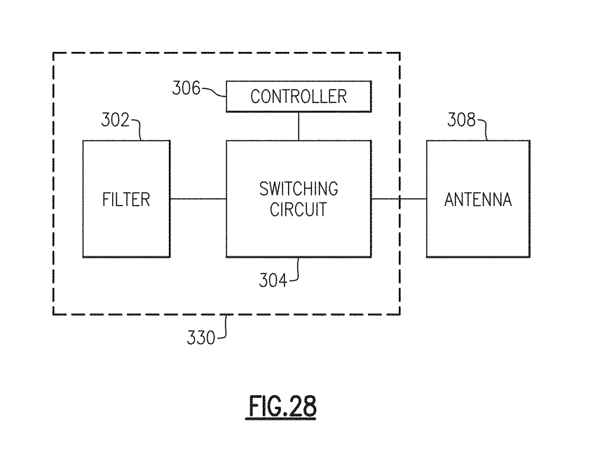

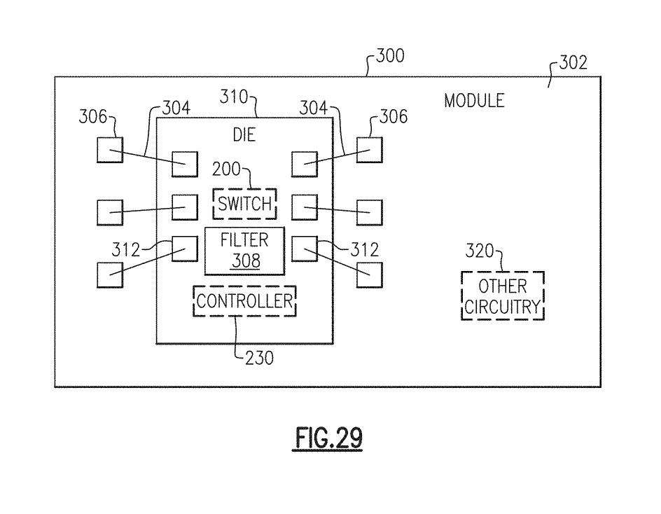

FIGS. 27A and 27C are perspective views taken by a SEM showing cross-sections of packaging structures that have each been successfully transferred to a receiving substrate 120. As shown, each structure includes a wall and lid structure that was formed on a preparation substrate using a photolithographic method such as process 300. Once transferred to the receiving substrate, the wall and lid structure form a cavity 105 that packages electronic devices disposed on the receiving substrate. The lids of the wall and lid examples shown in FIGS. 27A and 27C are each sized and shaped to extend slightly beyond the edges of the walls. FIGS. 27B and 27D are the respective figure drawings for FIGS. 27A and 27C.

Embodiments of the structure material described herein can be included in an electronic device or component and/or can be integrated into a variety of different modules including, for example, a stand-alone module, a front-end module, a module combining the component with an antenna switching network, an impedance matching module, an antenna tuning module, or the like. FIG. 28 is a block diagram of a device 330, such as a wireless device, that can be fabricated according to one or more of the processes described herein. Such a device 330 can include one or more acoustic wave filters 302, such as SAW or BAW filters or other similar acoustic wave components, and can be packaged according to one or more of the embodiments as described herein. The device 330 can also include a switching circuit 304. In some embodiments, control of the switching circuit 304 can be performed or facilitated by a controller 306. The device 330 can also be configured to be in communication with an antenna 308.

Embodiments of the structure material disclosed herein, optionally packaged into the device 330 or the module 300 discussed below, may be advantageously used in a variety of electronic devices. Non-limiting examples of the electronic devices can include consumer electronic products, parts of the consumer electronic products, electronic test equipment, cellular communications infrastructure such as a base station, etc. Examples of the electronic devices can include, but are not limited to, a mobile phone such as a smart phone, a telephone, a television, a computer monitor, a computer, a modem, a hand held computer, a laptop computer, a tablet computer, an electronic book reader, a wearable computer such as a smart watch, a personal digital assistant (PDA), a microwave, a refrigerator, an automobile, a stereo system, a DVD player, a CD player, a digital music player such as an MP3 player, a radio, a camcorder, a camera, a digital camera, a portable memory chip, a health care monitoring device, a vehicular electronics system such as an automotive electronics system or an avionics electronic system, a washer, a dryer, a washer/dryer, a peripheral device, a wrist watch, a clock, etc. Further, the electronic devices can include unfinished products.

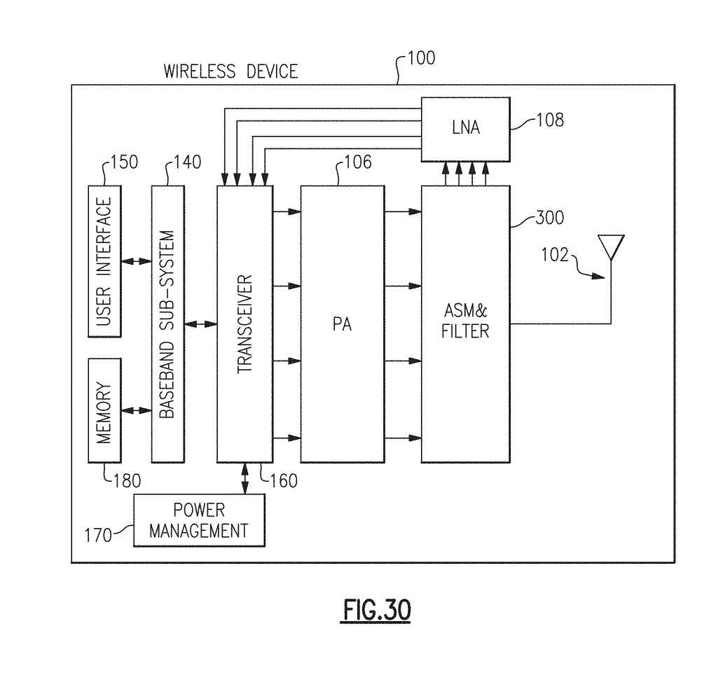

As discussed above, the structure material described herein may be used to package electronic devices such as a mobile communications device or other electronic device. FIG. 29 is a block diagram of one example of a module 300, such as an antenna switch module, that can include an embodiment of the structure material described herein. The module 300 includes a packaging substrate 302 that is configured to receive a plurality of components. In some embodiments, such components can include a die 310 that is packaged according to one or more features as described herein. For example, the die 310 can be formed from a receiving substrate 130 as described above and may be packaged using one or more of the transferred structures, such as the wall and lid structure described herein. The die may also include an acoustic wave filter 308, such as a SAW or BAW filter or other similar acoustic wave component, a switch 200, such as an antenna switch, and optionally other circuitry or components, such as a controller 230, for example. A plurality of connection pads 312 can facilitate electrical connections such as wirebonds 304 to connection pads 306 on the substrate 302 to facilitate passing of various power and signals to and from the die 310. In some embodiments, other circuitry or components 320 can be mounted on or formed on the packaging substrate 302. For example, the components 320 may include phase shifters, filter circuitry, modulators, demodulators, down converters, and the like, as would be known to one of skill in the art of semiconductor fabrication in view of the disclosure herein. In some embodiments, the packaging substrate 302 can include a laminate substrate.

In some embodiments, the module 300 can also be packaged using the structure material as described herein. For example, the structure material may be prepared on a separate substrate and may configured to form one or more packaging structures to, for example, provide protection and facilitate easier handling of the module 300. In certain instances, the packaging structure may include an overmold formed over the packaging substrate 302 that is dimensioned to substantially encapsulate the various circuits and components thereon. It will be understood that although the module 300 is described in the context of wirebond-based electrical connections, one or more features of the present disclosure can also be implemented in other packaging configurations, including flip-chip configurations.

In some implementations, a device packaged according to one or more of the embodiments described herein can be included in an RF device such as a wireless device. The packaging structures described herein can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, a wireless router, a wireless access point, a wireless base station, modem, communication network, or any other portable or non-portable device configured for voice and/or data communication.

FIG. 30 is a block diagram of a wireless device 100 that, according to certain embodiments, may implement the structure material disclosed herein. The wireless device 100 can be a cellular phone, smart phone, tablet, modem, or any other portable or non-portable device configured for voice or data communications. The wireless device 100 includes an antenna 102 and can transmit and receive signals from the antenna 102.

The wireless device 100 further includes a transceiver 160. The transceiver 160 is configured to generate signals for transmission and/or to process received signals. Signals generated for transmission are received by the power amplifier (PA) 106, which amplifies the generated signals from the transceiver 160. Received signals are amplified by the low noise amplifier (LNA) 108 and then provided to the transceiver 160. The antenna switch module and filter component 300 can be configured to perform one or more functions. For instance, the antenna switch module portion of the component 300 can switch between different bands and/or modes, transmit and receive modes, etc. The acoustic wave filter of component 300 may be used to perform a filtering function of the signal so as to allow through desired channels(s). As is also shown in FIG. 30, the antenna 102 both receives signals that are provided to the transceiver 160 via the antenna switch module and filter component 300 and the LNA 108 and also transmits signals from the wireless device 100 via the transceiver 160, the PA 106, and the antenna switch module and filter component 300. However, in other examples multiple antennas can be used. Although not shown in FIG. 30, the antenna switch module and filter component 300 may be implemented as separate components.

The power amplifier 106 can be used to amplify a wide variety of RF or other frequency-band transmission signals. For example, the power amplifier 106 can receive an enable signal that can be used to pulse the output of the power amplifier to aid in transmitting a wireless local area network (WLAN) signal or any other suitable pulsed signal. The power amplifier 106 can be configured to amplify any of a variety of types of signal, including, for example, a Global System for Mobile (GSM) signal, a code division multiple access (CDMA) signal, a W-CDMA signal, a Long Term Evolution (LTE) signal, or an EDGE signal. In certain embodiments, the power amplifier 106 and associated components including switches and the like can be fabricated on GaAs substrates using, for example, pHEMT or BiFET transistors, or on a Silicon substrate using CMOS transistors.

The wireless device 100 further includes a power management system 170 that is connected to the transceiver 160 and that manages the power for the operation of the wireless device 100. The power management system 160 can also control the operation of the baseband processing circuitry 140 and other components of the wireless device 100. The power management system provides power to the various components of the wireless device 100. Accordingly, in certain examples the power management system 170 may include a battery. Alternatively, the power management system 170 may be coupled to a battery (not shown).

The baseband processing circuitry 140 is shown to be connected to a user interface 150 to facilitate various input and output of voice and/or data provided to and received from a user. The baseband processing circuitry 140 can also be connected to a memory 180 that is configured to store data and/or instructions to facilitate the operation of the wireless device, and/or to provide storage of information for the user.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while acts of the disclosed processes are presented in a given order, alternative embodiments may perform routines having acts performed in a different order, and some processes or acts may be deleted, moved, added, subdivided, combined, and/or modified. Each of these processes or acts may be implemented in a variety of different ways. Also, while processes or acts are at times shown as being performed in series, these processes or acts may instead be performed in parallel, or may be performed at different times.

The teachings of the invention provided herein can be applied to other systems, not necessarily the system described above. The elements and acts of the various embodiments described above can be combined to provide further embodiments.

Having thus described several aspects of at least one example, it is to be appreciated that various alterations, modifications, and improvements will readily occur to those skilled in the art. For instance, examples disclosed herein may also be used in other contexts. Such alterations, modifications, and improvements are intended to be part of this disclosure, and are intended to be within the scope of the examples discussed herein. Accordingly, the foregoing description and drawings are by way of example only.

What is claimed is:

1-13. (canceled)

14. A transferable structure for use in packaging an electronic device, comprising:
at least one layer of structure material disposed on temporary bonding material that at least partially covers a surface of a preparation substrate, the at least one layer of structure material constructed and arranged to form at least a portion of a package that hermetically seals an electronic device.

15. The transferable structure of claim 14 wherein the at least one layer of structure material is constructed and arranged to form walls and a lid for a cavity that surrounds the electronic device.

16. The transferable structure of claim 14 wherein the layer of structure material is a photosensitive polymer.

17. The transferable structure of claim 14 disposed in a packaged module of an electronic device.

18-20. (canceled)

21. The transferable structure of claim 15 wherein the at least one layer of structure material includes a first layer of structure material that defines the lid and a second layer of structure material that defines the walls.

22. The transferable structure of claim 15 wherein the walls have a thickness of at least 0.001 inches.

23. A packaged electronic device, comprising:
a substrate;
at least one electronic device disposed on the substrate; and
an encapsulation structure having walls formed from at least one layer of structure material that form a perimeter around the at least one electronic device.

24. The packaged electronic device of claim 23 wherein the encapsulation structure further comprises a lid formed from at least one layer of the structure material and attached to the walls such that the walls and lid of the encapsulation structure define a cavity that encapsulates the at least one electronic device.

25. The packaged electronic device of claim 24 wherein the lid is sized and shaped so as to extend slightly beyond an outer edge of the walls.

26. The packaged electronic device of claim 24 wherein the layer of structure material is a polymer.

27. The packaged electronic device of claim 26 wherein the polymer is a polyimide.

28. The packaged electronic device of claim 26 wherein the polymer is photosensitive.

29. The packaged electronic device of claim 24 further comprising an adhesion layer disposed on at least a portion of an outer surface of the encapsulation structure.

30. The packaged electronic device of claim 29 further comprising a metal seed layer disposed on the adhesion layer.

31. The packaged electronic device of claim 30 further comprising a conductive pad disposed on at least a portion of the metal seed layer.

32. The packaged electronic device of claim 23 further comprising electrodes disposed on the substrate.

33. The packaged electronic device of claim 32 wherein the walls and lid of the encapsulation structure are configured to form a lip that bonds to at least a portion of the electrodes.

34. A preparation substrate for use in forming a packaged electronic device comprising:
a substrate;
a layer of temporary bonding material disposed a surface of the substrate; and
at least one layer of structure material disposed on at least a portion of the temporary bonding material, the at least one layer of structure material constructed and arranged to form walls and a lid for a cavity that encapsulates an electronic device.

35. The preparation substrate of claim 34 further including a layer of metal disposed on at least a portion of a surface of the lid.

36. The preparation substrate of claim 34 wherein the structure material is a photosensitive polymer.
